(19) United States
(12) Patent Application Publication
(10) Pub. No.: US 2023/0025796 A1
(43) Pub. Date: Jan. 26, 2023

(54) SEMICONDUCTOR DEVICE

(71) Applicant: SEIKO EPSON CORPORATION, Tokyo (JP)

(72) Inventor: Hiroyuki SHIMADA, CHUO-SHI (JP)

(73) Assignee: SEIKO EPSON CORPORATION, Tokyo (JP)

(21) Appl. No.: 17/868,805

(22) Filed: Jul. 20, 2022

(30) Foreign Application Priority Data
Jul. 21, 2021 (JP) 2021-121036

(51) Int. Cl. H01L 29/778; H01L 29/20; H01L 21/02; H01L 21/306; H01L 21/78; H01L 29/66

(52) U.S. Cl. CPC H01L 29/7788; H01L 21/0242; H01L 21/0254; H01L 21/0262; H01L 21/02631; H01L 21/7806; H01L 21/30612; H01L 29/2003; H01L 29/66462

(57) ABSTRACT

A semiconductor device includes a plurality of column portions including a semiconductor. The plurality of column portions each includes a source region, a drain region, and a channel formation region including a channel formed between the source region and the drain region. The semiconductor device further includes a gate electrode provided, via an insulating layer, at a side wall of the channel formation region, and also includes a first semiconductor layer provided at a side wall of the drain region. A conductive type of the first semiconductor layer differs from a conductive type of the semiconductor included in the drain region.

The present application is based on, and claims priority from JP Application Serial Number 2021-121036, filed on Jul. 21, 2021, the disclosure of which is hereby incorporated by reference herein in its entirety.

### BACKGROUND

### 1. Technical Field

The present disclosure relates to a semiconductor device.

### 2. Related Art

A semiconductor nanowire is a semiconductor thin wire having a thickness of the order of nanometers (nm), and is the configuration of a next-generation nano-device that has been attracting attention in terms of applications to various types of semiconductor devices such as a transistor or light source. In addition, by employing a Gate-All-Around (GAA) structure in which the entire circumferential direction of the semiconductor nanowire is surrounded by a gate electrode, it is possible to surround a channel formation region of the semiconductor nanowire with the gate electrode, make it fully depleted, and improve the controllability of electric-current. With the GAA structure, it is possible to achieve both a property in which ON and OFF are switched rapidly in terms of time and the high density per area.

For example, F.Yu et al., “Vertical architecture for enhancement mode power transistors based on GaN nanowires”, Appl. Phys. Lett. Vol. 108, 213503 (2016) discloses a semiconductor device including a plurality of semiconductor nanowires made of gallium nitride (GaN). In the semiconductor device disclosed in F.Yu et al., “Vertical architecture for enhancement mode power transistors based on GaN nanowires”, Appl. Phys. Lett. Vol. 108, 213503 (2016), the plurality of semiconductor nanowires are arranged in one direction at the front surface of a substrate so as to be spaced apart from each other, and each of the semiconductor nanowires extends along a direction perpendicular to the one direction described above. That is, the plurality of semiconductor nanowires are formed in a stripe manner when viewed along a direction perpendicular to the front surface of the substrate. In addition, a channel of a vertical transistor is comprised of an a-plane of GaN. Chromium (Cr) is used for the gate electrode.

The plurality of semiconductor nanowires of the semiconductor device disclosed in F.Yu et al., “Vertical architecture for enhancement mode power transistors based on GaN nanowires”, Appl. Phys. Lett. Vol. 108, 213503 (2016) are formed in a top-down manner using a process of dry etching. After the process of dry etching, a wet process using an alkaline chemical solution is used to recover the crystalline of GaN of the plurality of semiconductor nanowires. This results in an increase in the pitch of the semiconductor nanowires, which makes it difficult to achieve the high density of the semiconductor nanowire per area in the array surface. In addition, in a case of the process using the alkaline chemical solution described above or the like, the a-plane of GaN is likely to be formed as a channel surface, which makes it difficult to increase the surface density. Furthermore, with the semiconductor device disclosed in F.Yu et al., “Vertical architecture for enhancement mode power transistors based on GaN nanowires”, Appl. Phys. Lett. Vol. 108, 213503 (2016), after the semiconductor nanowires are formed, the gate electrode is formed by depositing Cr diagonally relative to the side wall of the semiconductor nanowire, which makes it difficult to control the gate length. Due to these factors, with the semiconductor device disclosed in F.Yu et al., “Vertical architecture for enhancement mode power transistors based on GaN nanowires”, Appl. Phys. Lett. Vol. 108, 213503 (2016), it is difficult to sufficiently reduce the on resistance to a level that is required for a power device.

### SUMMARY

In order to solve the problem described above, a semiconductor device according to one aspect of the present disclosure includes a plurality of column portions including a semiconductor. The plurality of column portions each includes a source region, a drain region, and a channel formation region including a channel formed between the source region and the drain region. The semiconductor device according to one aspect of the present disclosure further includes a gate electrode provided, via an insulating layer, at a side wall of the channel formation region, and a first semiconductor layer provided at a side wall of the drain region. A conductive type of the first semiconductor layer differs from a conductive type of the semiconductor included in the drain region.

### BRIEF DESCRIPTION OF THE DRAWINGS

FIG. 1 is a perspective view illustrating a semiconductor device according to an embodiment of the present disclosure.

FIG. 2 is a cross-sectional view illustrating the semiconductor device in FIG. 1 as viewed toward the arrow of the line C1-C1 in FIG. 1.

FIG. 3 is a cross-sectional view used to explain a method of manufacturing the semiconductor device illustrated in FIGS. 1 and 2.

FIG. 4 is a cross-sectional view used to explain a method of manufacturing the semiconductor device illustrated in FIGS. 1 and 2.

FIG. 5 is a cross-sectional view used to explain a method of manufacturing the semiconductor device illustrated in FIGS. 1 and 2.

FIG. 6 is a cross-sectional view used to explain a method of manufacturing the semiconductor device illustrated in FIGS. 1 and 2.

FIG. 7 is a cross-sectional view used to explain a method of manufacturing the semiconductor device illustrated in FIGS. 1 and 2.

FIG. 8 is a cross-sectional view used to explain a method of manufacturing the semiconductor device illustrated in FIGS. 1 and 2.

FIG. 9 is a cross-sectional view used to explain a method of manufacturing the semiconductor device illustrated in FIGS. 1 and 2.

FIG. 10 is a cross-sectional view used to explain a method of manufacturing the semiconductor device illustrated in FIGS. 1 and 2.

FIG. 11 is a cross-sectional view used to explain a method of manufacturing the semiconductor device illustrated in FIGS. 1 and 2.

FIG. 12 is a cross-sectional view used to explain a method of manufacturing the semiconductor device illustrated in FIGS. 1 and 2.

FIG. 13 is a cross-sectional view used to explain a method of manufacturing the semiconductor device illustrated in FIGS. 1 and 2.

FIG. 14 is a cross-sectional view used to explain a method of manufacturing the semiconductor device illustrated in FIGS. 1 and 2.

FIG. 15 is a cross-sectional view used to explain a method of manufacturing a semiconductor device illustrated in FIGS. 1 and 2.

FIG. 16 is a cross-sectional view used to explain a method of manufacturing a semiconductor device illustrated in FIGS. 1 and 2.

FIG. 17 is a cross-sectional view used to explain a method of manufacturing a semiconductor device illustrated in FIGS. 1 and 2.

FIG. 18 is a cross-sectional view used to explain a method of manufacturing a semiconductor device illustrated in FIGS. 1 and 2.

FIG. 19 is a cross-sectional view used to explain a method of manufacturing a semiconductor device illustrated in FIGS. 1 and 2.

FIG. 20 is a cross-sectional view used to explain a method of manufacturing a semiconductor device illustrated in FIGS. 1 and 2.

### DESCRIPTION OF EXEMPLARY EMBODIMENTS

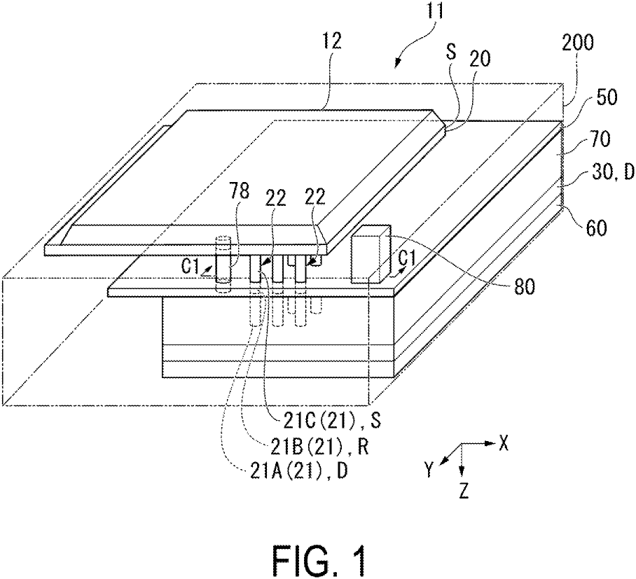

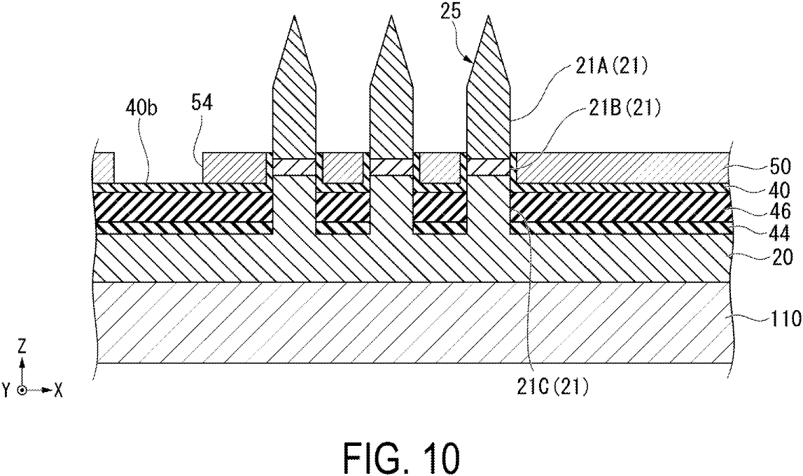

Below, an embodiment according to the present disclosure will be described with reference to FIGS. 1 to 20.

In each of the drawings below, the scale of the dimension may be changed depending on the constituent elements in order to facilitate viewing the independent constituent elements.

### Basic Structure of Semiconductor Device

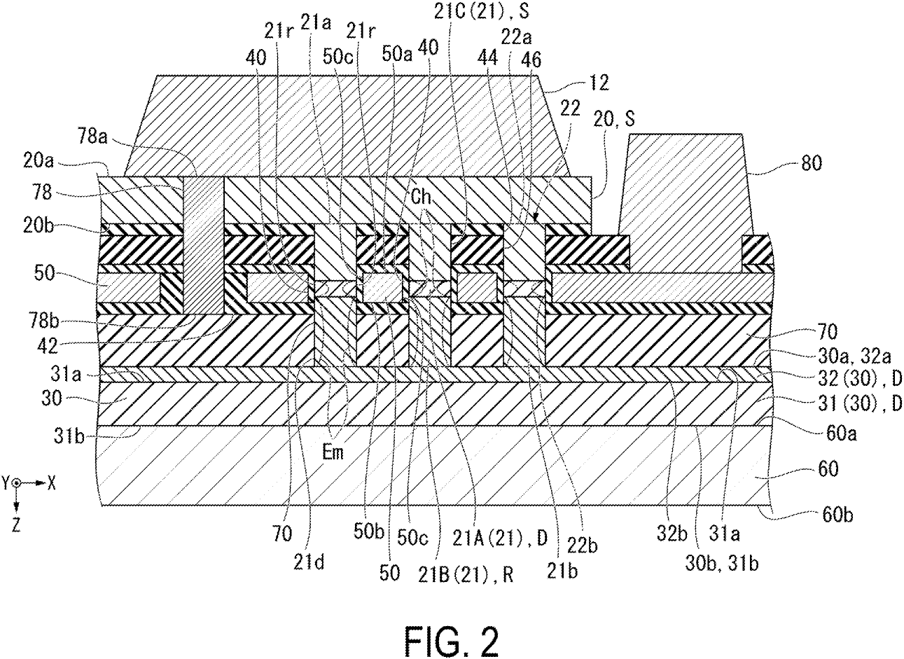

FIG. 1 is a perspective view illustrating a semiconductor device 11 according to an embodiment of the present disclosure. FIG. 2 is a cross-sectional view illustrating the semiconductor device 11 as viewed toward the arrow of the line C1-C1 in FIG. 1. As illustrated in FIGS. 1 and 2, the semiconductor device 11 includes a plurality of vertical-type field effect transistors (FET), and is used, for example, as a power device such as an inverter. The semiconductor device 11 mainly includes a metal layer 12 that constitutes a contact region at a source side; a semiconductor layer (second semiconductor layer) 20 and a semiconductor layer (semiconductor) 21C, each of which constitutes a source region S of the FET; a semiconductor layer (semiconductor) 21A and a semiconductor layer 30, each of which constitutes a drain region D of the FET; a semiconductor layer (semiconductor) 21B and a gate insulating film (insulating layer) 40, each of which constitutes a channel formation region R of the FET; a gate electrode 50; a metal layer (first metal layer) 60 that constitutes a contact region at a drain side of the FET; and a semiconductor layer (first semiconductor layer) 70. Note that, although illustration is not given in FIG. 1, the gate insulating film 40 is interposed between the semiconductor layer 21B and the gate electrode 50 as described later.

Below, the Z direction is, for example, a direction parallel to a thickness direction of the metal layer 12 of the semiconductor device 11 and directed from the front surface 12a of the metal layer 12 toward the back surface 12b. The X direction and the Y direction are two directions each parallel to the front surface 12a of the metal layer 12 and perpendicular to each other. The Z direction is perpendicular to the X direction and the Y direction.

In addition to each of the configurations described above, the semiconductor device 11 includes, for example, a gate conductive layer coupled directly to the gate electrode 50 in the Z direction, and a gate metal layer provided at an opposite side of the gate conductive layer from the gate electrode 50 side, although illustration is not given. Furthermore, the semiconductor device 11 may include, for example, a source conductive layer coupled directly to the semiconductor layer 20 of the source region S in the Z direction, and a source metal layer provided at an opposite side of the source conductive layer from the semiconductor layer 20 side. Alternatively, a wire bonding may be provided at the gate electrode 50, and a wire bonding may be provided at the metal layer 12. The gate conductive layer and the source conductive layer function as a contact plug. The gate metal layer functions as a contact terminal to the gate electrode 50, and the source metal layer functions as a contact terminal to the source region S of the FET. Each of the gate conductive layer and the source conductive layer is made, for example, of tungsten (W). The gate metal layer and the source metal layer are each made of a metal such as copper (Cu) or aluminum (Al). When the wire bonding is provided at the gate electrode 50 and the wire bonding is provided at the metal layer 12, each of the wire bondings may be made of a metal such as copper (Cu) or aluminum (Al).

As illustrated in FIGS. 1 and 2, the metal layer 60 functions as a base member configured to support the main members of the semiconductor device 11. In addition, the metal layer 60 extends along the X-Y plane and has a predetermined thickness. When having a constant thickness, a metal layer has a strength higher than a semiconductor layer. Thus, the predetermined thickness may be thinner than that of a semiconductor substrate used in a typical semiconductor device. A front surface 60a and a back surface 60b of the metal layer 60 are flat surfaces substantially parallel to the X-Y plane. The metal layer 60 is made, for example, of a metal such as Cu.

The semiconductor layer 30 is stacked on the back of the front surface 60a of the metal layer 60 in the Z direction. In addition, the semiconductor layer 30 extends along the X-Y plane and has a predetermined thickness. A front surface 30a and a bottom surface 30b of the semiconductor layer 30 are flat surfaces substantially parallel to the X-Y plane. The semiconductor layer 30 is made, for example, of an n-type semiconductor. The n-type semiconductor is, for example, gallium nitride (GaN) doped with an n-type impurity. The n-type impurity includes, for example, silicon (Si) or the like.

The semiconductor layer 30 has a two-layer structure including a first layer 31 and a second layer 32. The first layer 31 extends along the X-Y plane, and is disposed at the rearward side of the semiconductor layer 30 in the Z direction, that is, at a lower portion of the semiconductor layer 30. A bottom surface 31b of the first layer 31 is in contact with the front surface 60a of the metal layer 60. The second layer 32 is provided between the first layer 31 and each of the plurality of column portions 22 in the Z direction. In addition, the second layer 32 extends along the X-Y plane, and is disposed at the frontward side of the semiconductor layer 30 in the Z direction, that is, at an upper portion of the semiconductor layer 30. A front surface 32a of the second layer 32 is in contact with the bottom surfaces 22b of the plurality of column portions 22. A bottom surface 32b of the second layer 32 is in contact with the front surface 31a of the first layer.

The first layer 31 is made of an n-type semiconductor, and is made, for example, of n-type GaN. Below, GaN doped with the n-type impurity may be referred to as n-GaN. The second layer 32 is made of an n-type semiconductor having the impurity concentration lower than the n-type semiconductor that constitutes the first layer 31. Hereinafter, of the n-GaN, n-GaN having a relatively high impurity concentration is also referred to as n⁺-GaN, and n-GaN having a relatively low impurity concentration is also referred to as n⁻-GaN. In other words, the first layer 31 is made of n⁺-GaN and the second layer 32 is made of n⁻-GaN.

The semiconductor layer 21A, the semiconductor layer 21B, and the semiconductor layer 21C are stacked sequentially in the Z direction, and have the same shape and the same size within the X-Y plane. In addition, the semiconductor layer 21A, the semiconductor layer 21B, and the semiconductor layer 21C constitute one column portion (column portion) 22. The column portion 22 is a so-called semiconductor nanowire. In other words, the semiconductor device 11 includes a plurality of column portions 22. The plurality of column portions 22 are arranged at predetermined intervals along the X direction and the Y direction. The plurality of column portions 22 each protrude in a direction parallel to and opposite to the Z direction, from a front surface 20a in a predetermined region of the semiconductor layer 20 that constitutes the source region S. The cross section of each of the plurality of column portions 22 that intersects the X-Y plane has, for example, a circular shape, but may have a rectangle shape or a polygon shape other than the rectangle shape.

The maximum size of each of the plurality of column portions 22 within the X-Y plane is, for example, approximately 0.3 µm, and is at least equal to or less than 0.5 µm. By setting the plurality of column portions 22 to have a small diameter as described above, the region Ch where a channel is formed easily reaches the substantial center portion of the semiconductor layer 21C within the X-Y plane, which makes it possible to achieve full depletion.

Note that the term “semiconductor” in Claims collectively represents the semiconductor 21 that constitutes the column portion 22. This, however, does not mean that all the semiconductor layers 21A, 21B, and 21C are made of the same type of semiconductor, and does include semiconductors of the same type having different impurity concentrations or semiconductors of different types with conditions or the like that will be described later being met.

The semiconductor layer 21A is disposed at the foremost portion of the column portion 22 in the Z direction, that is, disposed at the lowermost layer, and constitutes the drain region D together with the semiconductor layer 30. A bottom surface 22b of each of the plurality of column portions 22 is in contact with the front surface 30a of the semiconductor layer 30. With the arrangement described above, the semiconductor layer 30 is coupled to the semiconductor layer 21A of each of the plurality of column portions 22. The semiconductor layer 21A is made of an n-type semiconductor, and is made, for example, of the same n⁻-GaN as the second layer 32 of the semiconductor layer 30. In addition, although illustration is not given, the semiconductor layer 21A that constitutes the drain region D includes a first region, and a second region having the impurity concentration lower than the first region, and the second region may be disposed between the first region and the semiconductor layer 21B. In this case, the impurity concentration of the second region is lower than the first region and is greater than the semiconductor layer 21B. The second region is a drift region.

The semiconductor layer 21B is disposed at an intermediate layer disposed between the semiconductor layers 21A and 21C of the column portion 22 in the Z direction, and constitutes the channel formation region R. The channel formation region R includes the region Ch where a channel formed between the source region S and the drain region D is formed, and is a region where a gradient is formed due to a difference in the impurity concentrations of the semiconductors 21 that constitute the semiconductor layers 21A and 21C, and the drift velocity of electric charge is increased by receiving the gate voltage. The size of the semiconductor layer 21B in the Z direction is smaller than the size of each of the semiconductor layers 21A and 21C in the Z direction.

The semiconductor layer 21B is made, for example, of a semiconductor not doped with an impurity. A semiconductor that is not doped with an impurity includes, for example, GaN. Hereinafter, GaN for which almost no doping of an impurity is performed may be referred to as i-GaN. Note that it is only necessary that the semiconductor layer 21B is made of a semiconductor having an impurity concentration lower than the n-type semiconductor that constitutes the semiconductor layer 21A and the semiconductor layer 21C, and is not necessarily limited to the semiconductor not doped with an impurity. However, as the impurity concentration of the semiconductor layer 21B gets closer to the impurity concentration of the semiconductor layer 21A, the on resistance of the FET reduces, and the withstand voltage also reduces. The on resistance and the withstand voltage are in a relationship of trade-off. The impurity concentration of the semiconductor layer 21B is set on an as-necessary basis by considering the impurity concentration of the semiconductor layer 21A, the size of the semiconductor layer 21A in the Z direction, and the relationship of trade-off described above. In the semiconductor device 11 according to the present embodiment, as described below, the semiconductor layer 21B and the semiconductor layer 70 constitute a super junction (SJ) structure, and with the SJ structure, the on-resistance is reduced. Thus, it is preferable to set the impurity concentration of the semiconductor layer 21B to be lower in order to secure the withstand voltage of the FET, and the impurity concentration of the semiconductor layer 21B is preferably close to zero at which no impurity is doped.

Note that it is preferable that the semiconductor that constitutes the semiconductor layers 21A, 21B, and 21C belongs to the same type, and is, for example, GaN in the present embodiment. By forming the semiconductor layers 21A, 21B, and 21C using the same type of semiconductor 21, it is possible to continuously and easily perform a process of forming the plurality of column portions 22 at the time of manufacturing the semiconductor device 11.

In addition, GaN is able to convert electrical power more efficiently than that of other semiconductors, and hence, GaN is able to output, per volume, relatively high electrical power. For example, the band gap of GaN is approximately three times greater than that of Si commonly used in a typical power device. Furthermore, the dielectric breakdown field of GaN is greater than Si by an order of magnitude, and hence, GaN achieves lower on resistance by approximately three orders of magnitude than the performance limitation resulting from Si. In addition, the saturation electron velocity of GaN is greater than that of Si or the like, and hence, it is possible to achieve the faster operation of the semiconductor device 11.

The semiconductor layer 21C is disposed at the rearmost portion of the column portion 22 in the Z direction, that is, at the uppermost layer, and constitutes the source region S. The size of the semiconductor layer 21C in the Z direction is greater than at least the size of the semiconductor layer 21B in the Z direction, and is slightly smaller than the size of the semiconductor layer 21A in the Z direction. The semiconductor layer 21C is made, for example, of an n-type semiconductor. The n-type semiconductor is n-GaN doped, for example, with an n-type impurity such as Si as described above.

The impurity concentration of the n-type semiconductor that constitutes the semiconductor layer 21C is at least higher than the impurity concentration of the semiconductor that constitutes the semiconductor layer 21B and is higher than the impurity concentration of the semiconductor that constitutes the semiconductor layer 21A. In other words, in each of the plurality of column portions 22, the semiconductor layer 21A is made of n⁻-Gan, the semiconductor layer 21B is made of i-GaN, and the semiconductor layer 21C is made of n⁺-GaN. That is, both the impurity concentration of the first region and the impurity concentration of the second region of the semiconductor layer 21A are lower than the impurity concentration of the semiconductor layer 21C.

The size of the semiconductor layer 21A in the Z direction is greater than the size of the semiconductor layer 21C and the impurity concentration of the semiconductor that constitutes the semiconductor layer 21A is lower than that of the semiconductor layer 21C. This secures a wide depletion layer of the FET and also secures the withstand voltage of the semiconductor device 11. In addition, with the plurality of column portions 22, vertical FETs are configured, and the size of the semiconductor layer 21B in the Z direction is reduced to be smaller than that of the semiconductor layer 21A, 21C. Furthermore, GaN is used as the semiconductor 21. This configuration reduces the on resistance per area at the front surface 30a of the semiconductor layer 30 of the semiconductor device 11 to a certain degree.

The semiconductor layer 20 constitutes the source region S together with the semiconductor layer 21C. The semiconductor layer 20 extends along the X-Y plane, and couples semiconductor layers 21C of the plurality of column portions 22 to each other along the X-Y plane. The bottom surface 20b of the semiconductor layer 20 is in contact with the front surfaces 22a of the plurality of column portions 22. With the arrangement described above, the semiconductor layer 30 is coupled to the semiconductor layer 21C of each of the plurality of column portions 22. The semiconductor layer 20 is made of the same semiconductor as the semiconductor layers 30, 21A, 21B, and 21C, and is made of GaN. The semiconductor layer 20 is made, for example, of an n-type semiconductor, and in the present embodiment, is made of n⁺-GaN as with the semiconductor layer 21C. In other words, in the semiconductor device 11, the semiconductor layers 20 and 21C, and the first layer 31 of the semiconductor layer 30 are made of n⁺-GaN. The semiconductor layer 21A and the second layer 32 of the semiconductor layer 30 are made of n⁻-Gan. In addition, the semiconductor layer 21B is made of i-GaN.

The metal layer 12 is stacked at the front surface 20a of the semiconductor layer 20 to form a contact region, and is coupled to the semiconductor layer 20. The metal layer 12 is disposed so as to be opposed to the metal layer 60 in the Z direction, and functions as a counter member configured to support the main members of the semiconductor device 11, and has a predetermined thickness. The front surface 12a and the back surface 12b of the metal layer 12 are flat surfaces substantially parallel to the X-Y plane. The metal layer 12 is made, for example, of a metal such as aluminum (Al) or Cu.

The gate electrode 50 is provided at least at a side wall 21r of the semiconductor layer 21B of the channel formation region R with the gate insulating film 40 being interposed between the gate electrode 50 and the side wall 21r. The size of the gate electrode 50 in the Z direction is greater than that of the semiconductor layer 21B. When viewed in the Z direction, the gate electrode 50 overlaps with the end portion, at the channel formation region R side, of the semiconductor layer 21A and an end portion, at the channel formation region R side, of the semiconductor layer 21C. That is, the size of the gate electrode 50 in the Z direction is greater than that of the semiconductor layer 21B. In plan view as viewed from the Z direction, the gate electrode 50 is provided so as to surround the periphery of each of the column portions 22. That is, in plan view as viewed from the Z direction, the gate electrode 50 is provided so as to surround the channel formation region R. The gate electrode 50 includes, for example, a polycrystalline silicon (Poly-Si), and is made of Poly-Si doped with boron (B). Poly-Si doped with B has a high work function among materials that can constitute the gate electrode. As the sufficiently high work function is achieved, it is possible to achieve a positive threshold voltage (that is, Normally Off) of the semiconductor device 10.

The gate insulating film 40 is provided at a side wall 50c and a front surface 50a of the gate electrode 50. In other words, in the X-Y plane, the gate insulating film 40 is interposed between the gate electrode 50 and the semiconductor layer 21B. The gate insulating film 40 is made, for example, of silicon oxide (SiO₂).

An insulating layer 46 and a mask insulating film 44 are stacked sequentially at the front surface 40a of the gate insulating film 40 in the Z direction. A front surface 46a of the insulating layer 46 overlaps with the front surface 22a of each of the plurality of column portions 22 in the Z direction, and is formed so as to be substantially flush with a front surface 21A of the semiconductor layer 21C. The size of the insulating layer 46 in the Z direction is greater than that of the mask insulating film 44. The insulating layer 46 is made, for example, of glass including SiO₂ as a main component or is made of SiO₂ or the like. The mask insulating film 44 is made, for example, of SiO₂.

An insulating layer 42 is provided at a bottom surface 50b of the gate electrode 50. The insulating layer 42 is made, for example, of glass including SiO₂ as a main component or of SiO₂ or the like. The gate electrode 50 interposed between the plurality of column portions 22 is surrounded by the gate insulating film 40 and the insulating layer 42. In addition, the gate electrodes 50 are coupled to each other at a predetermined region of the semiconductor device 11 that differs from a region of which cross section is illustrated in FIG. 2, and are disposed so as to be able to be supplied with a gate voltage.

The semiconductor layer 70 is provided between the insulating layer 42 and the second layer 32 of the semiconductor layer 30 in the Z direction, and is provided at the side wall 21d of the semiconductor layer 21A of the drain region D. The semiconductor layer 70 is in contact with the semiconductor layer 21A at the X-Y plane. A bottom surface 70b of the semiconductor layer 70 overlaps with the bottom surface 22b of each of the plurality of column portions 22 in the Z direction, and is formed so as to be substantially flush with a bottom surface 21B of the semiconductor layer 21A. The semiconductor layer 70 is electrically coupled to the semiconductor layers 20 and 21C of the source region S through the metal plug 78 that will be described later.

The conductive type of the semiconductor layer 70 differs from at least the conductive type of the semiconductor 21 that constitutes the semiconductor layer 21A. The semiconductor layer 70 is made, for example, of a p-type semiconductor. The p-type semiconductor includes, for example, GaN doped with a p-type impurity. The p-type impurity includes, for example, magnesium (Mg), zinc (Zn), and the like. Hereinafter, GaN doped with a p-type impurity may be referred to as p-GaN. In addition, of p-GaN, p-GaN having a relatively higher impurity concentration may be referred to as p⁺⁻GaN, and p-GaN having a relatively lower impurity concentration may be referred to as p⁻-GaN. The high or low of the impurity concentration is independent of the electrical conductivity of the semiconductor.

In the semiconductor device 11, the side wall 21d of the semiconductor layer 21A that constitutes the drain region D of each the plurality of column portions 22 and the semiconductor layer 70 are adjacent to each other, and the semiconductor layers 21A and 70 are PN joined to each other, thereby configuring the SJ structure. Specifically, there is provided an SJ structure including the semiconductor layer 21A made of n⁻-GaN and the semiconductor layer 70 made of p⁺⁻GaN. With the SJ structure with the semiconductor layer 70, a depletion layer Em of the semiconductor layer 21A is supported from the outside in the radial direction along the X-Y plane. This makes it possible to minimize the on resistance while securing the withstand voltage of the vertical-type FET at each of the plurality of column portions 22 as described above. By reducing the on resistance per area at the front surface 30a of the semiconductor layer 30, it is possible to increase the switching frequency at the time of causing the semiconductor device 11 to switch. This makes it possible to improve the power density of the semiconductor device 11 as a power supply, and achieve the high performance as the power device. In addition, the semiconductor layer 70 may be provided at a side wall of the second region, or may be provided at a side wall of the first region. Furthermore, the semiconductor layer 70 may be provided at both side walls of the first region and the second region. With the semiconductor layer 70 being provided at the side wall of the second region having lower impurity concentration, it is possible to increase the expansion of the depletion layer Em from the outside in the radial direction along the X-Y plane, and reduce the on resistance while securing the withstand voltage of the FET.

The insulating layer 46 and the mask insulating film 44 are provided sequentially toward a direction opposite to the Z direction and between the gate electrode 50 and the semiconductor layer 20 in the Z direction. A front surface 44a of the mask insulating film 44 overlaps with the front surface 22a of each of the plurality of column portions 22 in the Z direction, and is formed so as to be substantially flush with the front surface 21A of the semiconductor layer 21C. Column portions 22 adjacent to each other at the X-Y plane are separated by the semiconductor layer 70, the insulating layer 42, the gate insulating film 40, the insulating layer 46, and the mask insulating film 44. As with the insulating layer 42, the insulating layer 46 is made, for example, of glass including SiO₂ as the main component, or is made of SiO₂ or the like. The mask insulating film 44 is made, for example, of SiO₂ or silicon nitride (SiN).

The semiconductor device 11 further includes a metal plug 78 and a conductive layer 80. The metal plug 78 couples the metal layer 12 and the semiconductor layer 70 in the Z direction. A front surface 78a of the metal plug 78 is in contact with the back surface 12b of the metal layer 12. A bottom surface 78b of the metal plug 78 is in contact with a front surface 70a of the semiconductor layer 70. The metal plug 78 penetrates through the semiconductor layer 20, the mask insulating film 44, the insulating layer 46, the gate insulating film 40, and the insulating layer 42, each of which is interposed in the Z direction between the metal layer 12 and the semiconductor layer 70 in a region where the plurality of column portions 22 are not formed in the X-Y plane. The metal plug 78 is electrically coupled to the semiconductor layer 21C of each of the plurality of column portions 22 through the semiconductor layer 20 that constitutes the source region S. Thus, the source voltage supplied from the metal layer 12 to the semiconductor layers 20 and 21C is also supplied to the semiconductor layer 70 through the metal plug 78. The metal plug 78 is made of a conductive material. The conductive material described above includes, for example, W. The metal plug 78 corresponds to a “metal conductive layer” in CLAIMS.

The conductive layer 80 is coupled to the gate electrode 50 in a predetermined region where the plurality of column portions 22 are not formed in the X-Y plane, to supply a gate voltage directly to the gate electrode 50. The conductive layer 80 penetrates, in the Z direction, through the insulating layer 46 and the mask insulating film 44 that are stacked at the gate electrode 50 in a predetermined region.

As illustrated in FIG. 1, in a region within the X-Y plane other than the region where the plurality of column portions 22 are formed, an interlayer insulating layer 200 is provided as appropriate, for example, between the metal layers 12 and 60 and between the semiconductor layer 70, the semiconductor layer 20 of the source region S, the plurality of column portions 22, and the like.

In the semiconductor device 11 described above, the impurity concentration of the semiconductor layer 21B is set to be lower than the impurity concentration of the semiconductor layer 21A, 21C. In addition, when the gate electrode 50 is not supplied with a positive voltage equal to or more than a threshold value, no electric current flows between the drain region D and the source region S. In a state where the gate voltage is 0 V and the gate electrode 50 is supplied with a voltage less than the threshold value, the region Ch of the semiconductor layer 21C is substantially completely depleted. Once the gate electrode 50 is supplied with a positive voltage equal to or more than the threshold value, the region Ch of channel is formed at the semiconductor layer 21B of the channel formation region R adjacent to the gate electrode 50 with the gate insulating film 40 being interposed therebetween. Electrons of n⁺―GaN that constitutes the semiconductor layer 21C of the source region S and electrons of n⁻―GaN that constitutes the semiconductor layer 21A of the drain region D are strongly attracted to the region Ch, which makes the region Ch serve as a flow path of electrons. This results in a flow of electric current between the drain region D and the source region S. The size of the region Ch of channel formed at the channel formation region R is controlled on the basis of the voltage supplied to the gate electrode 50, and the value of electric current flowing between the drain region D and the source region S changes. With the gate electrode 50, the electric current between the drain region D and the source region S is controlled.

In the semiconductor device 11, the semiconductor layer 70 is interposed between semiconductor layers 21A at the X-Y plane as described above to form the SJ structure. In the semiconductor device 11, a depletion layer Em is split from the interface between the semiconductor layers 21B and 21A into both sides of the semiconductor layer 70 made of p⁺―GaN and is formed along the side wall 21d. Thus, the interface having a large difference in impurity concentration expands further than that in the structure that does not have the SJ structure. This makes the electric field intensity lower than the maximum value of the electric field intensity of the semiconductor device 11, and makes the electric field intensity substantially constant from the interface between the semiconductor layers 21B and 21A to the interface between the semiconductor layers 21A and 20. Generally, in order to prevent break down from occurring in the semiconductor device, the withstand voltage is set so as not to exceed the maximum value of the electric field intensity determined on the basis of a material of a semiconductor. Furthermore, when the horizontal axis is the position in the Z direction and the vertical direction is the electric field intensity, the withstand voltage of the semiconductor device is determined on the basis of the area of the distribution of the electric field intensity. In a case of the semiconductor device 11, it is possible to reduce the maximum value of the electric field intensity while securing the area of the distribution of the electric field intensity. In addition, in the semiconductor device 11, as the maximum value of the electric field intensity reduces, it is possible to increase the density of carrier, which makes it possible to reduce the on resistance.

### Method of Manufacturing Semiconductor Device

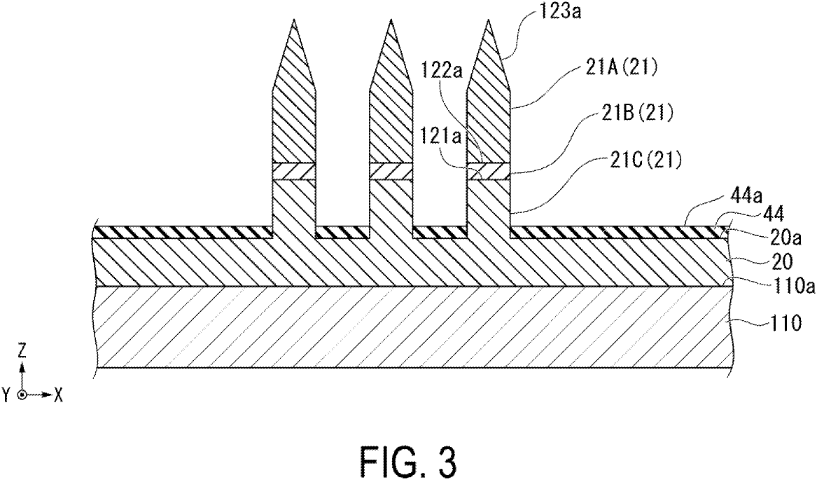

Next, a method of manufacturing the semiconductor device 11 according to the present embodiment will be described. FIGS. 3 to 20 are cross-sectional views each illustrating each step of the method of manufacturing the semiconductor device 11.

As illustrated in FIG. 3, crystal of n⁺―GaN is first caused to grow at a front surface 110a of a substrate 110 used to grow GaN crystal, for example, by using a molecular beam epitaxy method (MBE), a metal organic chemical vapor deposition (MOCVD) method, or the like to form the semiconductor layer 20. For example, a sapphire substrate can be used for the substrate 110.

Next, a film of SiO₂ is formed at the front surface 20a of the semiconductor layer 20, for example, by using a chemical vapor deposition (CVD) method or a physical vapor deposition (PVD) method, to form the mask insulating film 44. Then, only the mask insulating film 44 stacked at a region of the front surface 20a of the semiconductor layer 20 where the plurality of column portions 22 are to be formed is removed, for example, by using photolithography or an etching method, to cause the front surface 20a of the semiconductor layer 20 of this region to be exposed.

Next, for example, by using the MBE, crystal of n⁺―GaN is caused to grow to have a predetermined height in the Z direction at the front surface 20a of the semiconductor layer 20 that has been exposed in the previous step, to form the semiconductor layer 21C. Then, the front surface 121A, which is eventually to be the bottom surface, of the semiconductor layer 21C is flattened so as to be parallel to the X-Y plane, and crystal of i-GaN is caused to grow at this front surface 121A to have a predetermined height in the Z direction by, for example, using the MBE, to form the semiconductor layer 21B. Furthermore, a front surface 122a, which is eventually to be a bottom surface, of the semiconductor layer 21B is flattened, and for example, the MBE is used to cause crystal of n⁻―GaN to grow at this front surface 122a to have a predetermined height in the Z direction, to form the semiconductor layer 21A. Alternatively, it may be possible to consecutively form the 21C, 21B, and 21A by varying the concentration of dopant, for example, the concentration of Si. In other words, in the method of manufacturing the semiconductor device 11, the semiconductor 21 that constitutes the column portion 22 is formed in the bottom-up manner in the Z direction from the semiconductor layer 20 that is eventually to be the source region S.

A front surface 123a of the semiconductor layer 21A may have concave and convex relative to the X-Y plane, and may not be flattened in the stage illustrated in FIG. 3. Note that, when each of the semiconductor layers 21C, 21B, and 21A are caused to grow by using the MBE, concave and convex are generated at each of the front surfaces. Thus, it is preferable to cause each of the semiconductor layers 21C, 21B, and 21A to grow in the Z direction to have a sufficient height so that the minimum size of each of the semiconductor layers 21C, 21B, and 21A in the Z direction is equal to or greater than the size, in the Z direction, of the semiconductor layer 21A, 21B, 21C of each of the column portions 22 illustrated in FIG. 2.

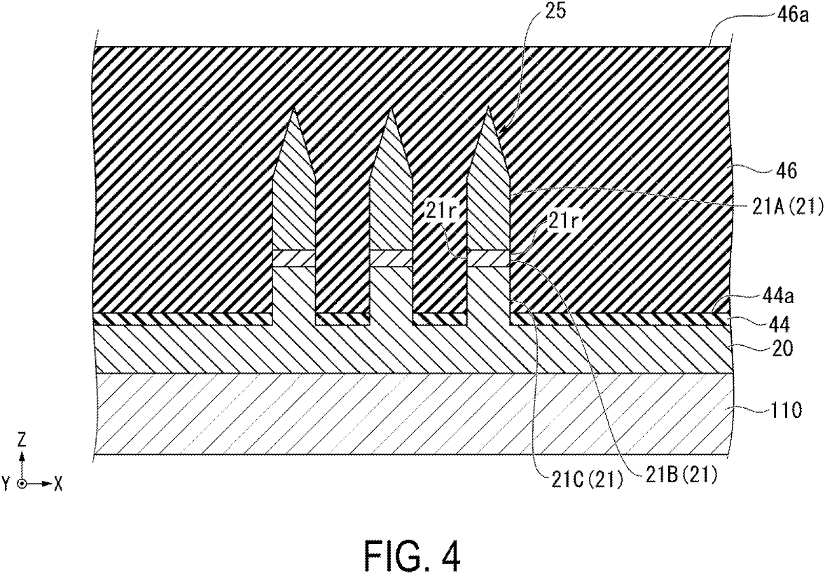

Next, for example, by using a spin coating method, a spin-on-glass (SOG) solution is applied and processing is performed so as to cover the front surface 44a, which is eventually to be the bottom surface, of the mask insulating film 44 and the columnar body 25 comprised of the semiconductor layers 21C, 21B, and 21A, to form the insulating layer 46 made of SiO₂ or the like as illustrated in FIG. 4. Through this process, the side wall 21r of the semiconductor layer 21B, the side wall of each of the semiconductor layers 21C and 21A, and the front surface of the semiconductor layer 21A are in contact with the insulating layer 46. The front surface 46a of the insulating layer 46 is disposed at a position higher than the leading end of the columnar body 25 in the Z direction, that is, more forward in the Z direction.

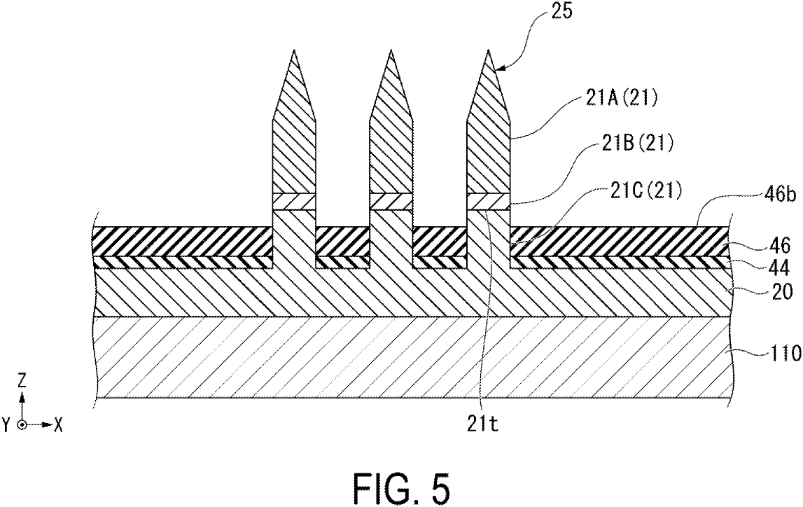

Next, as illustrated in FIG. 5, etching back is performed to the insulating layer 46 until the front surface 46a reaches an appropriately more rearward position in the Z direction than the bottom surface 21t, which is eventually to be a front surface, of the semiconductor layer 21B of the columnar body 25.

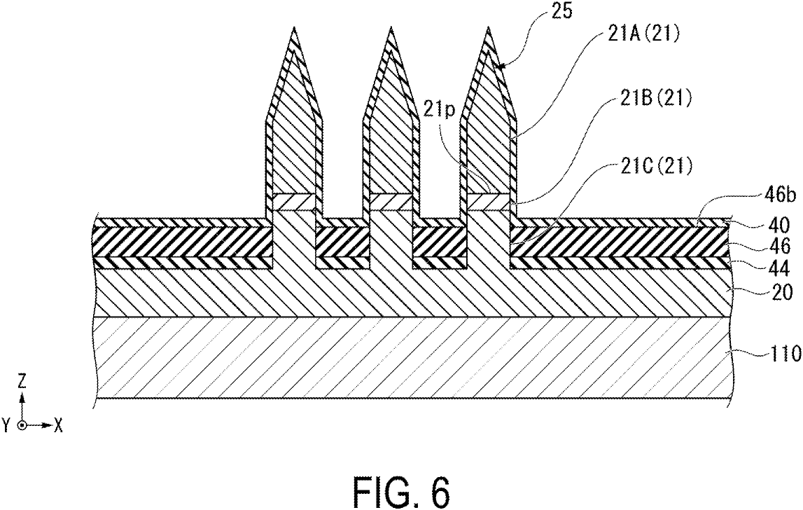

Next, for example, by using an atomic layer deposition (ALD) method, SiO₂ is deposited in a film manner so as to cover the front surface 46a of the insulating layer 46 and the side wall of and the front surface of the exposed columnar body 25, to form the gate insulating film 40 as illustrated in FIG. 6.

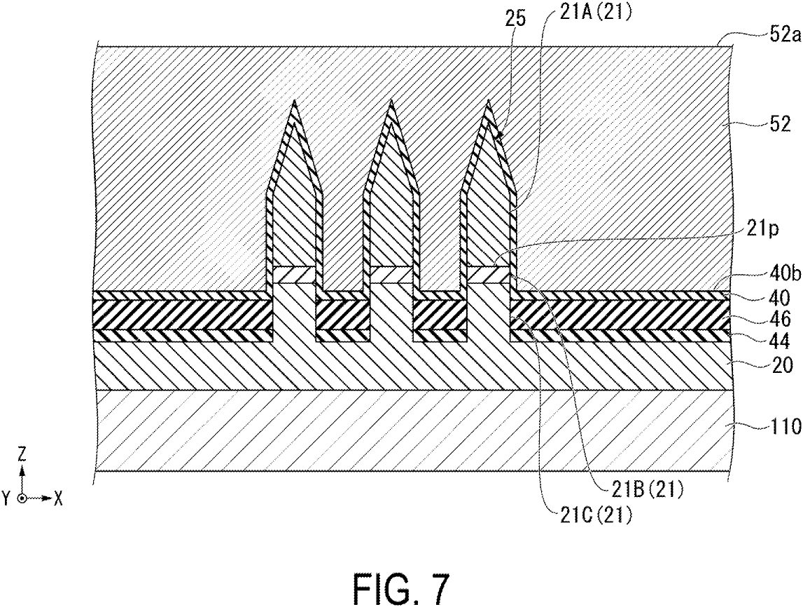

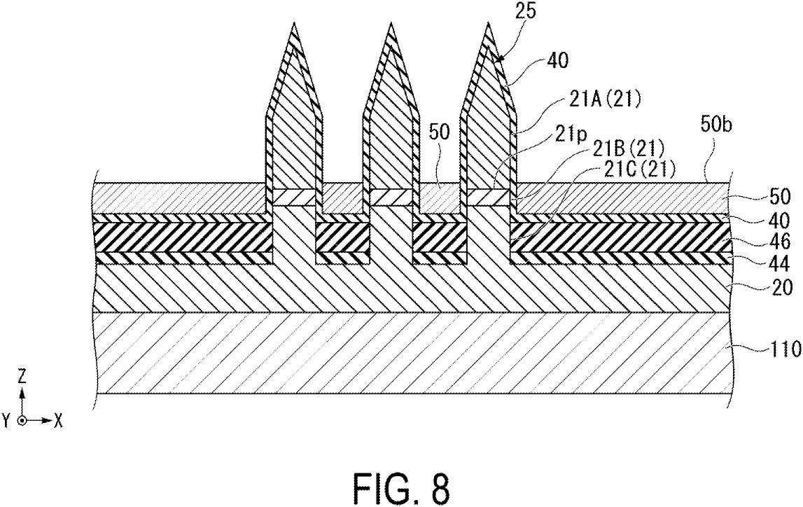

Next, B-doped Poly-Si is deposited in the Z direction from the front surface, which is eventually to be the bottom surface 40b, of the gate insulating film 40 stacked at the insulating layer 46 up to a position that entirely covers the gate insulating film 40 that covers the columnar body 25, to form a precursor layer 52 of the gate electrode 50 as illustrated in FIG. 7. B-dope may be thermally diffused by injecting boron ions into Poly-Si. Then, etching back is performed to the precursor layer 52 until the front surface 52a reaches an appropriately more forward position in the Z direction than the front surface 21p, which is eventually to be the bottom surface, of the semiconductor layer 21B of the columnar body 25, to form the gate electrode 50, as illustrated in FIG. 8.

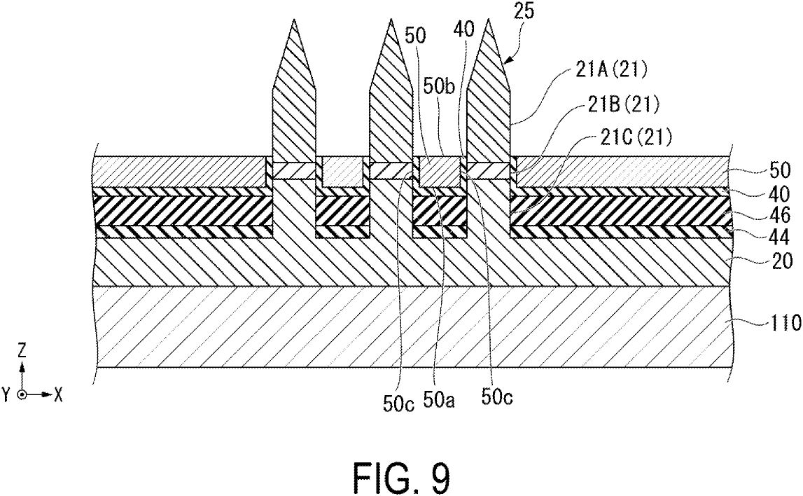

Next, as illustrated in FIG. 9, the gate insulating film 40 exposed in the Z direction from the front surface, which is eventually to be the bottom surface 50b, of the gate electrode 50 is removed, for example, through wet etching using a chemical solution or the like. With this process, the gate insulating film 40 that surrounds the side wall 50c and the front surface 50a of the gate electrode 50 is formed.

Next, for example, lithography and an etching method are used to form a through hole 54 in the gate electrode 50 in a region where the plurality of column portions 22 are not formed in the X-Y plane. The through hole 54 penetrates only through the gate electrode 50 in the Z direction. A front surface, which is eventually to be the bottom surface 40b, of the gate insulating film 40 is exposed at the bottom of the through hole 54.

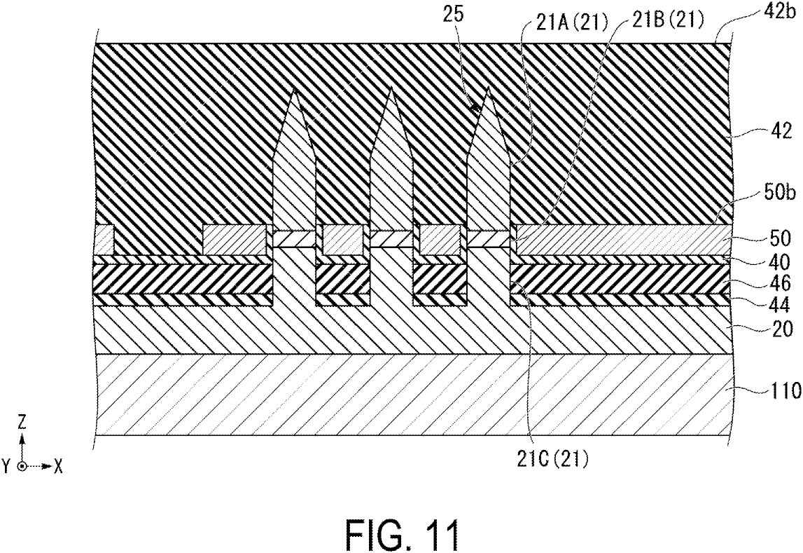

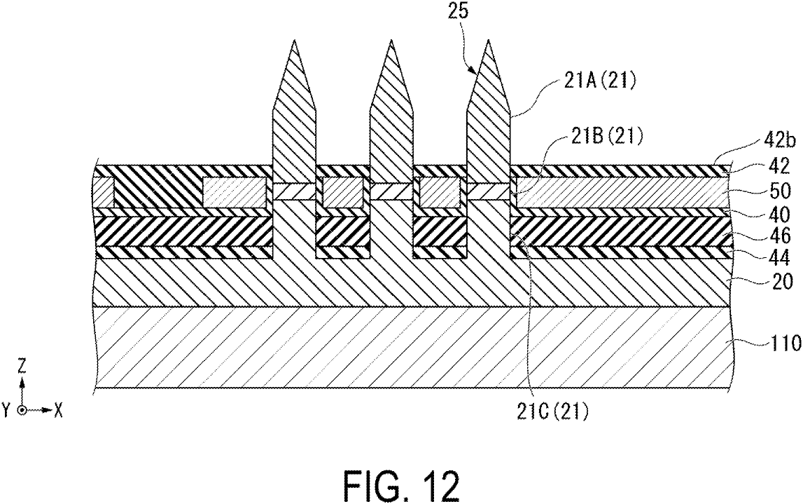

Next, the through hole 54 is filled, and a SOG solution is applied and processing is performed so as to cover an exposed columnar body 25 protruding in the Z direction from the bottom surface 50b of the gate electrode 50, to form the insulating layer 42, as illustrated in FIG. 11. Then, a chemical mechanical polishing (CMP) method or etching back is performed to the insulating layer 42 until the front surface, which is eventually to be the bottom surface 42b, of the insulating layer 42 reaches a position at the appropriately forward, in the Z direction, of the bottom surface 50b of the gate electrode 50, that is, reaches a position appropriately higher than the gate electrode 50, as illustrated in FIG. 12. At this time, the bottom surface 42b of the insulating layer 42 is flattened to be a flat surface.

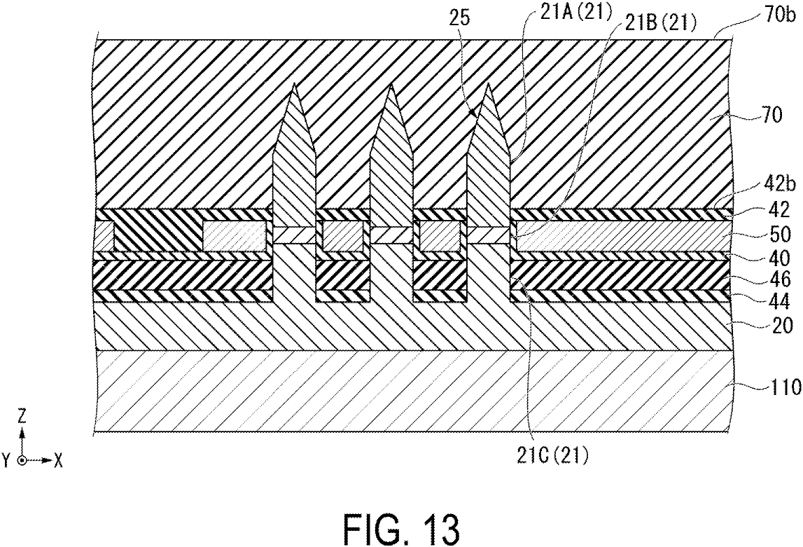

Next, as illustrated in FIG. 13, for example, a metal organic CVD (MOCVD) method is used to deposit p⁺―GaN so as to cover the exposed columnar body 25 protruding in the Z direction from the bottom surface 42b of the insulating layer 42, to form the semiconductor layer 70.

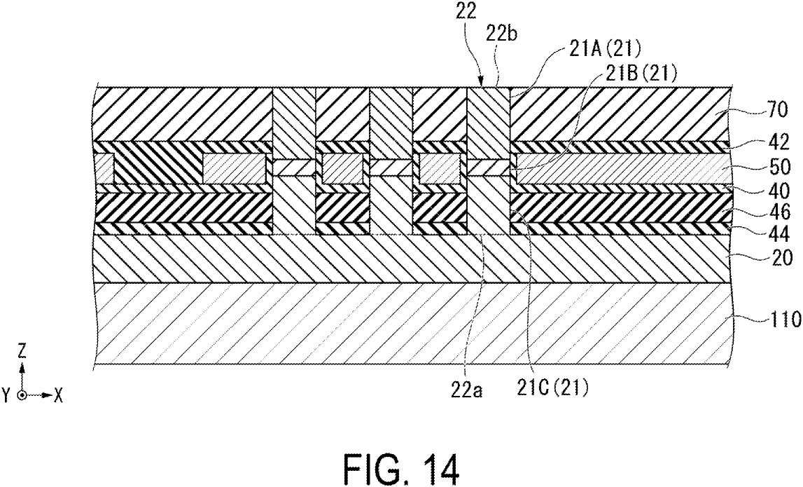

Next, for example, a thermal etching method using phosphoric acid or the like is used to remove the front portion of the semiconductor layer 70 in the Z direction. As illustrated in FIG. 14, the front surface, which is eventually to be the bottom surface 70b, of the semiconductor layer 70 is aligned with the most rearward side in the Z direction of the front surface of the semiconductor layer 21A having concave and convex and is also aligned with an appropriately more forward side in the Z direction than the front surface 21p of the semiconductor layer 21B, that is, aligned with a position higher than the semiconductor layer 21B. In this step, the bottom surface 70b of the semiconductor layer 70 is aligned with the bottom surface 22b of each of the plurality of column portions 22 and the bottom surface of the semiconductor layer 21A in the Z direction, and is flush with the bottom surface 22b. In this step, the plurality of column portions 22 protruding in the Z direction from the bottom surface 20b of the semiconductor layer 20 are formed.

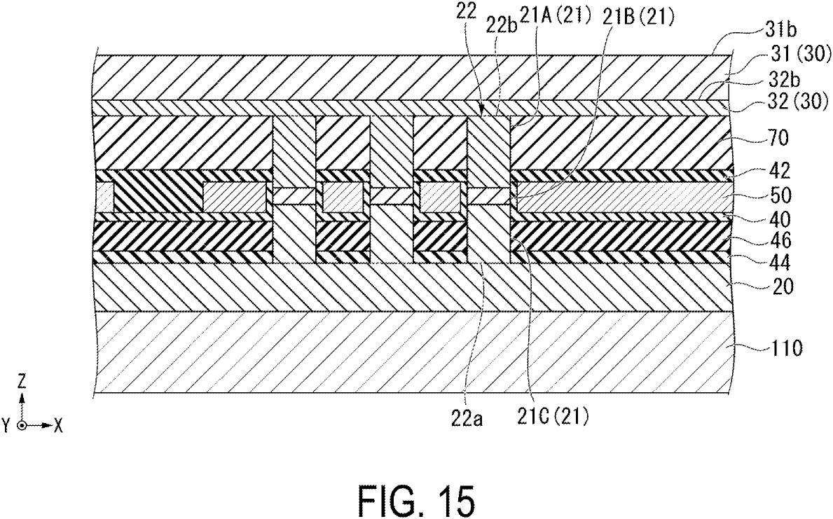

Next, as illustrated in FIG. 15, for example, the MBE is used to cause crystal of n⁻―GaN to grow to have a predetermined height in the Z direction over the entire flat surface comprised of the bottom surface 22b of each of the plurality of column portions 22 and the bottom surface 70b of the semiconductor layer 70, to form the second layer 32 of the semiconductor layer 30. Then, for example, by using the MBE, crystal of n⁺―GaN is caused to grow to have a predetermined height in the Z direction at the front surface, which is eventually to be the bottom surface 32b, of the second layer 32, to form the first layer 31 of the semiconductor layer 30.

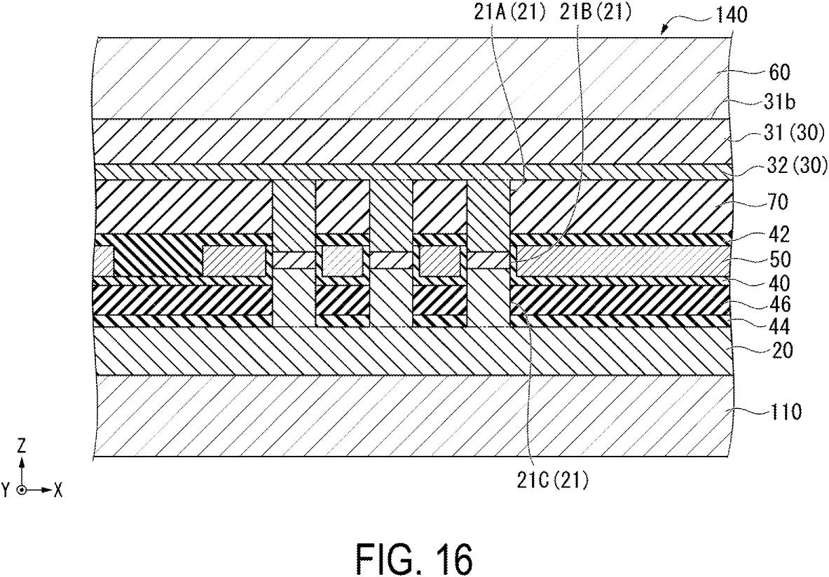

Next, an adhesive, which is not illustrated, is applied to the front surface, which is eventually to be the bottom surface 31b, of the first layer 31 of the semiconductor layer 30 to glue the metal layer 60 to the bottom surface 31b through the adhesive, as illustrated in FIG. 16. The adhesive used includes, for example, ultraviolet curing resin or thermosetting resin. However, there is no particular limitation, and it is possible to use any glue that can favorably glue the metal layer 60 to the bottom surface 30b of the semiconductor layer 30. For example, instead of the adhesive, metal for gluing may be deposited.

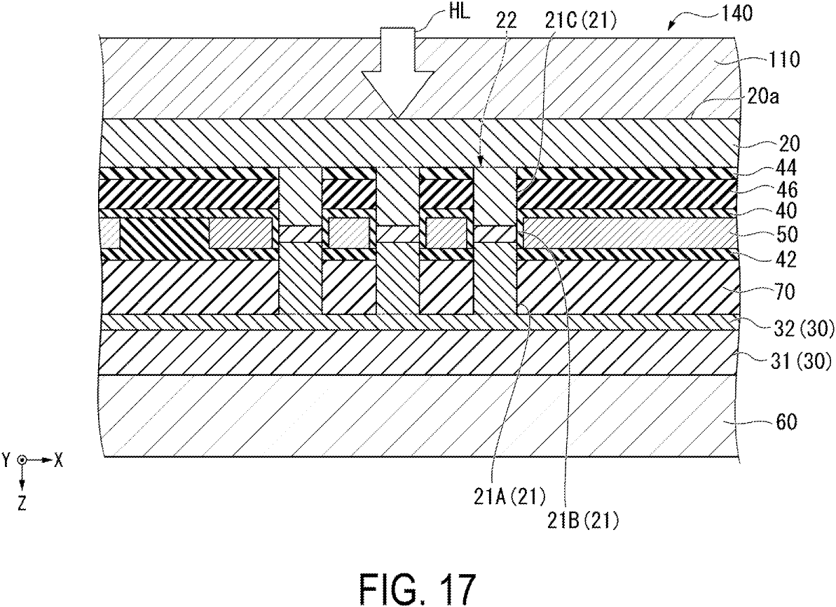

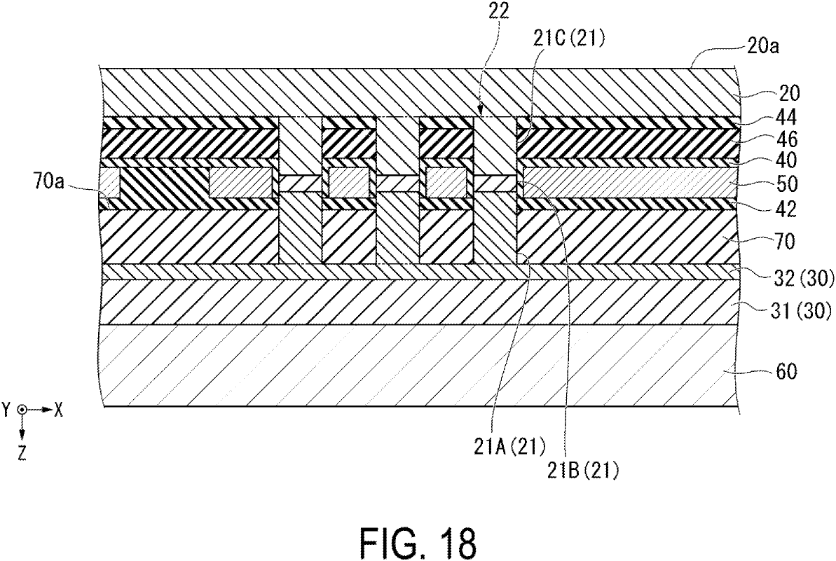

Next, the substrate 110 is removed from a stacked structural body 140 including the substrate 110, the semiconductor layers 20, 21C, 21B, and 21A, the mask insulating film 44, the insulating layer 46, the gate insulating film 40, the gate electrode 50, the insulating layer 42, the semiconductor layers 70 and 30, and the metal layer 60 that have been manufactured on and before the previous process. Specifically, as illustrated in FIG. 17, the stacked structural body 140 is inverted in the Z direction, and for example, a laser lift off (LLO) process is performed. In the LLO process, a high-power laser light source, which is not illustrated, emits laser light HL from behind the substrate 110 in the Z direction to peel the substrate 110 from the front surface 20a of the semiconductor layer 20 as illustrated in FIG. 18. When the substrate 110 is a sapphire substrate, krypton fluoride (KrF) excimer laser is preferable for the high-power laser light source. When the KrF excimer laser is used, the center wavelength of the laser light HL is approximately 248 nm.

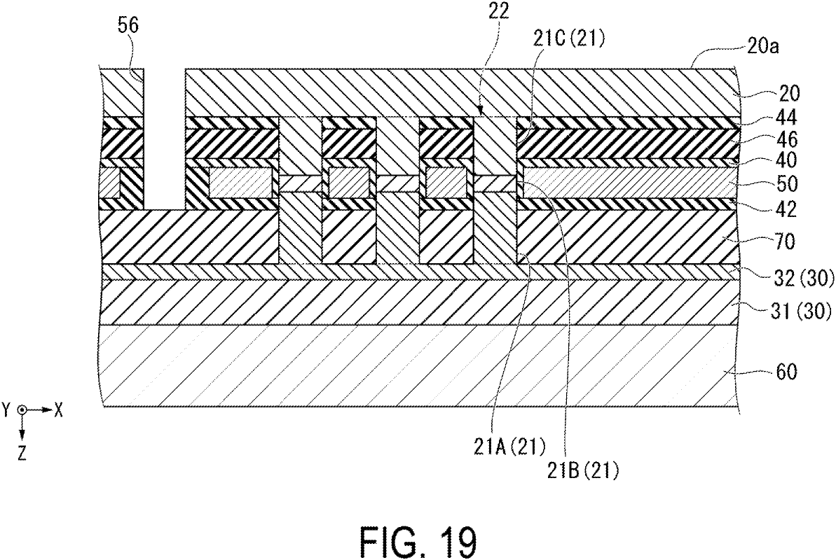

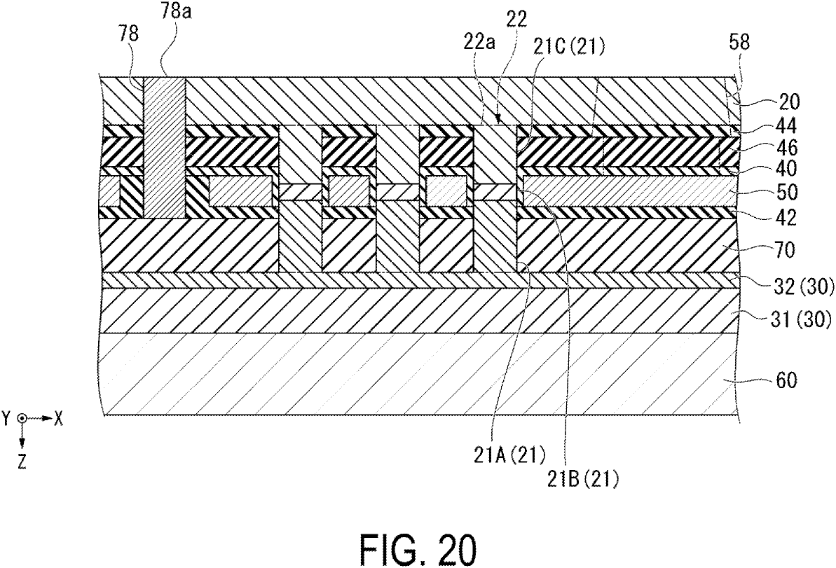

Next, in a region where the plurality of column portions 22 are not formed in the X-Y plane, a through hole 56 is formed in a region where the metal plug 78 illustrated in FIGS. 1 and 2 is formed, as illustrated in FIG. 19. The through hole 56 reaches the front surface 70a of the semiconductor layer 70 in the Z direction from the front surface 20a of the semiconductor layer 20 that is exposed after the substrate 110 is peeled off. The through hole 56 can be formed by using, for example, lithography and a dry etching method. Then, by using, for example, the CVD method, a conductive material such as W is deposited in the through hole 56 and is also deposited at a portion disposed at the rearward of the through hole 56 in the Z direction. After this, etching back is performed to the conductive layer until the front surface of the conductive layer comprised of the deposited conductive material is flush with the front surface 20a of the semiconductor layer 20. With this step, the metal plug 78 is formed as illustrated in FIG. 20.

Next, in a region where the plurality of column portions 22 are not formed in the X-Y plane and the conductive layer 80 illustrated in FIGS. 1 and 2 is formed, an opening is formed by removing the semiconductor layer 20, the mask insulating film 44, the insulating layer 46, and the gate insulating film 40 within a region 58 indicated by the dashed line in FIG. 20. The gate electrode 50 is exposed at the bottom of the formed opening. Then, although illustration is not given, a conductive material such as W is deposited in the opening and is also deposited at a portion disposed at the rearward of the opening in the Z direction, to form the conductive layer 80.

Next, an adhesive, which is not illustrated, is applied to the front surface of the semiconductor layer 20 and the front surface 78a of the metal plug 78 in a region that overlaps with the plurality of column portions 22 in the X-Y plane. Then, the metal layer 12 is glued through the adhesive. Note that this step may be performed after the formation of the metal plug 78 described above and before the formation of the conductive layer 80.

In addition, although illustration is not given, in a region within the X-Y plane other than the region where the plurality of column portions 22 are formed, lithography and a dry etching method are used to remove an interlayer insulating layer of a region where a gate conductive layer that is in contact with the gate electrode 50 is disposed, the interlayer insulating layer being disposed more toward the Z direction than the gate electrode 50. Through this process, a through hole is formed. In addition, for example, lithography and a CNT etching method are used to remove an interlayer insulating layer of a region where a source conductive layer that is in contact with the semiconductor layer 20 of the source region S is disposed, the interlayer insulating layer being disposed more toward the Z direction than the semiconductor layer 20. Through this process, a through hole is formed. Then, for example, a CVD method is used to deposit W within each through hole and at a portion disposed at the rearward of the through hole in the Z direction, to form a gate conductive layer and a source conductive layer. After this, etching back is performed to the gate conductive layer and the source conductive layer until the front surfaces of the gate conductive layer and the source conductive layer are flush with the front surface 20a of the semiconductor layer 20. An adhesive is used to glue the gate metal layer and the source metal layer to the front surfaces of the gate conductive layer and the source conductive layer. This process can be performed at appropriate timing by taking each of the processes described above into consideration. Alternatively, in a region within the X-Y plane other than the region where the plurality of column portions 22 are formed, it may be possible to form, for example, wire boding that is in contact with the gate electrode 50. In addition, wire bonding may be formed at the metal layer 12.

By performing the processes described above, the main structure of the semiconductor device 11 illustrated in FIGS. 1 and 2 is manufactured. Although illustration is not given, post processes are performed as necessary to complete the semiconductor device 11.

### Operation Effect

The semiconductor device 11 according to the present embodiment described above includes the plurality of column portions 22 comprised of the semiconductor 21. The plurality of column portions 22 each includes the source region S, the drain region D, the channel formation region R, the gate electrode 50, and the semiconductor layer 70. The channel formation region R includes a region (channel area) Ch of a channel formed between the source region S and the drain region D in the Z direction. The gate electrode 50 is provided at the side wall 21r of the semiconductor layer 21B that constitutes the channel formation region R with the gate insulating film 40 being interposed between the gate electrode 50 and the side wall 21r. The semiconductor layer 70 is provided at the side wall 21d of the semiconductor layer 21A that constitutes the drain region D. The conductive type of the semiconductor layer 70 differs from the conductive type of the semiconductor 21 of the semiconductor layer 21A.

The semiconductor device 11 according to the present embodiment includes a vertical-type FET having the GAA structure including the plurality of column portions 22 and the gate electrode 50 adjacent to the channel formation region R with the gate insulating film 40 being interposed between the channel formation region R and the gate electrode 50. In the semiconductor device 11, the column portion 22 having a very fine pitch of, for example, 0.5 µm or less is achieved at the X-Y plane. Furthermore, by arranging the semiconductor layer 70 adjacent to the semiconductor layer 21A of the drain region D of each of the plurality of column portions 22 in a direction along the X-Y plane, that is, in the horizontal direction, the SJ structure is formed, and the withstand voltage of the plurality of column portions 22 are supported from the horizontal direction. Thus, with the semiconductor device 11 according to the present embodiment, it is possible to achieve the significantly very low on resistance, as compared with the plurality of column portions 22 that do not include the semiconductor layer 70.

The plurality of column portions 22 of the semiconductor device 11 according to the present embodiment are formed, for example, in the bottom-up manner from the semiconductor layer 20, rather than a manufacturing method in the top-down manner using a dry etching process as with a typical semiconductor device. Specifically, crystals of n⁺―GaN, i-GaN, and n⁻―GaN are caused to sequentially grow from the bottom surface 20b of the semiconductor layer 20 made of n⁺―GaN in the Z direction. By causing GaN to grow in the bottom-up manner in this manner, it is possible to prevent the end portion at the base end side from expanding further than the end portion of the tip side as with a typical semiconductor nanowire, and it is also possible to form the column portion 22 having fine pitches and exhibiting high crystalline.

In addition, in the semiconductor device 11 according to the present embodiment, the gate electrode 50 is made of Poly-Si, and is doped with Br. Specifically, the gate electrode 50 is made of Poly-Si doped with Br. Furthermore, the semiconductors 21 of the semiconductor layers 21C, 21A, and 21B that constitute the source region S, the drain region D, and the channel formation region R of each of the plurality of column portions 22 are GaN. As described above, in the plurality of column portions 22 each having the GAA structure, the gate electrode 50 is made of a material having high work function. This makes it possible to increase the driving voltage of the semiconductor device 11, and reliably achieve the normally-off mode. In particular, using p-type Poly-Si makes it easy to achieve the normally-off mode. Although the high current drivability and the normally-off are in a relationship of trade-off, the semiconductor device 11 according to the present embodiment employs Poly-Si doped with Br as a material for the gate electrode 50, which makes it possible to achieve both the high current drivability and the normally-off mode.

Furthermore, in the semiconductor device 11 according to the present embodiment, the semiconductor layer 70 is electrically coupled to the source region S, and is electrically coupled to the semiconductor layer 20, 21C that constitutes the source region S. With the semiconductor device 11 according to the present embodiment, a source voltage is supplied to the semiconductor layer 70, and the depletion layer Em is supported at the semiconductor layer 21A of the drain region D of the column portion 22, whereby it is possible to obtain the withstand voltage.

In addition, in the semiconductor device 11 according to the present embodiment, the semiconductor layer 20 is coupled to the semiconductor layer 21C that constitutes the source region S of each of the plurality of column portions 22. With the semiconductor device 11 according to the present embodiment, the semiconductor layer 20 is interposed at the source region S between the plurality of column portions 22 each having a small diameter at the X-Y plane and the metal layer 12 extending at the X-Y plane. This makes it possible to suppress an increase in the contact resistance at the coupling between the semiconductor layer 21C and the conductive layer serving as a contact terminal at the source side, that is, the metal layer 12, prevent a deterioration in performance, and favorably perform operation.

Note that, in the semiconductor device 11 according to the present embodiment, the semiconductor layer 30 is coupled to the semiconductor layer 21A that constitutes the drain region D of each of the plurality of column portions 22. Thus, with the semiconductor device 11 according to the present embodiment, not only in the source region S but also in drain region D, the semiconductor layer 30 is interposed between the semiconductor layers 21A of the plurality of column portions 22 each having a small diameter at the X-Y plane and the metal layer 60 extending in the X-Y plane. This makes it possible to suppress an increase in the contact resistance at the coupling between the semiconductor layer 21A and the conductive layer serving as a contact terminal at the drain side, that is, the metal layer 60, and prevent a deterioration in performance.

In addition, in the semiconductor device 11 according to the present embodiment, the conductive type of each of the semiconductor 21 and the semiconductor layer 20 is an n-type, and the conductive type of the semiconductor layer 70 is a p-type. This configuration makes it possible to substantially completely deplete the region Ch of a channel of each of the plurality of column portions 22, and increase the velocity at which the electric charge moves. Thus, it is possible to improve the switching velocity of the semiconductor device 11 and the operational performance.

Furthermore, in the semiconductor device 11 according to the present embodiment, the metal layer 12 is coupled to the semiconductor layer 20 at the source side. The semiconductor device 11 according to the present embodiment makes it possible to favorably suppress an increase in the contact resistance between the semiconductor layer 21C and the metal layer 12 that is a contact terminal having high electrical conductivity at the source side. Note that, in the semiconductor device 11 according to the present embodiment, the metal layer 60 is coupled to the semiconductor layer 30 at the drain side. The semiconductor layer 30 has a stacked structure including the first layer 31 and the second layer 32. The semiconductor layer 21C and the second layer 32 are made of the same n⁻―GaN, and the first layer 31 is made of n⁺―GaN. In other words, the electrical conductivity increases in the order of the semiconductor layer 21C, the second layer 32, the first layer 31, and the metal layer 60. With the semiconductor device 11 according to the present embodiment having this configuration, it is possible to effectively suppress an increase in the contact resistance between the semiconductor layer 21A and the metal layer 12 that is a contact terminal having a high electrical conductivity at the drain side. In addition, the metal layers 12 and 60 function as the element substrate and the counter substrate of the semiconductor device 11, which makes it possible to achieve the thin semiconductor device 11 having a reduced weight.

Furthermore, in the semiconductor device 11 according to the present embodiment, the impurity concentration of the semiconductor layer 21A, made of n⁻―GaN, of the column portion 22 is lower than the impurity concentration of each of the semiconductor layer 70 and the first layer 31 of the semiconductor layer 30. The semiconductor layer 70 is made of p⁺―GaN and is in contact with the semiconductor layer 21A in the horizontal direction, and the first layer 31 is made of n⁺―GaN. Thus, it is possible to prevent movement of electric charge due to PN junction between the semiconductor layer 21A and the semiconductor layer 70 from directly coupling to the first layer 31 of the semiconductor layer 30, which makes it possible to prevent occurrence of break-down in the semiconductor device 11.

In addition, in the semiconductor device 11 according to the present embodiment, the source region S is coupled to the metal layer 12 and the semiconductor layer 70 through the metal plug 78 extending in the Z direction through the semiconductor layer 20. With the semiconductor device 11 according to the present embodiment, the source voltage is smoothly supplied from the metal layer 12 through the metal plug 78 to the semiconductor layers 20 and 70. In addition, the depletion layer Em is supported at the semiconductor layer 21A of the drain region D of the column portion 22, and it is possible to obtain the withstand voltage. It is possible to easily and stably manufacture the metal plug 78 using etching and a process of deposition, as compared with a case where the source region S is coupled to the metal layer 12 and the semiconductor layer 70 through a plug or the like made of a semiconductor. Thus, it is possible to enhance the reliability of operation of the semiconductor device 11.

These are detailed description of preferred embodiments according to the present disclosure. However, the present disclosure should not be limited to these particular embodiments, and can be modified or changed in a various manner within the scope of the main point of the present disclosure described in CLAIMS. Furthermore, the constituent elements of a plurality of embodiments can be combined on an as-necessary basis.

Furthermore, the semiconductor device according to the present disclosure can be applied to a power device such as an inverter as described in each of the embodiments described above. However, the application of the semiconductor device according to the present disclosure is not limited to the power device. For example, the semiconductor device according to the present disclosure may be mounted on a vehicle such as an automobile or mobile body such as an airplane, and can be applied to a semiconductor device or switching device that is required to have very low on resistance. In the semiconductor device according to the present disclosure, the material of each constituent elements can be changed according to application of the semiconductor device as long as this change does not interfere with the operation of the plurality of column portions 22 as the FET and the effect resulting from the SJ structure.

For example, in the semiconductor device according to the present disclosure, the semiconductor that constitutes the source region S, the drain region D, and the channel formation region R of each of the plurality of column portions is not limited to n-GaN nor GaN. The semiconductor of the column portion may be made of Si, gallium arsenide (GaAs), silicon carbide (SiC), or the like if these are permitted in the applications of the semiconductor device according to the present disclosure. Note that it is preferable that the semiconductor of the column portion exhibits an electrical characteristic suitable for each region in the FET by changing the impurity concentration.

For example, when the semiconductor device according to the present disclosure is used in a power device such as an inverter, it is preferable that the gate electrode is made of Poly-Si doped with Br in relation to the fact that the semiconductor that constitute each of the plurality of column portions is made of n-GaN. However, the gate electrode may be made, for example, of Al or W or an electrically conductive material including these metals, when the semiconductor that constitutes an FET of the semiconductor device according to the present disclosure is made of SiC and the application of the semiconductor device permits it. In this case, it is preferable that the gate electrode has a high work function relative to the semiconductor that constitutes the column portion.

The semiconductor device according to an aspect of the present disclosure may have the following configuration.

The semiconductor device according to an aspect of the present disclosure includes the plurality of column portions including the semiconductor. Each of the plurality of column portions includes the source region, the drain region, and the channel formation region disposed between the source region and the drain region. The semiconductor device according to one aspect of the present disclosure further includes the gate electrode provided, via the insulating layerr, at the side wall of the channel formation region and configured to control a current between the source region and the drain region, and includes the first semiconductor layer provided at the side wall of the drain region. The conductive type of the first semiconductor layer differs from the conductive type of the semiconductor included in the drain region.

In the semiconductor device according to one aspect of the present disclosure, the gate electrode may be made of polycrystalline silicon.

In the semiconductor device according to one aspect of the present disclosure, the gate electrode may be doped with boron.

In the semiconductor device according to one aspect of the present disclosure, the semiconductor may be gallium nitride.

In the semiconductor device according to one aspect of the present disclosure, the first semiconductor layer may be electrically coupled to the source region.

In the semiconductor device according to one aspect of the present disclosure, the second semiconductor layer may be coupled to the source region of each of the plurality of column portions.

The semiconductor device according to one aspect of the present disclosure may be configured such that the conductive type of each of the semiconductor and the second semiconductor layer is an n-type, and the conductive type of the first semiconductor layer is a p-type.

In the semiconductor device according to one aspect of the present disclosure, the metal layer may be coupled to the second semiconductor layer.

In the semiconductor device according to one aspect of the present disclosure, the source region may be coupled to the metal layer and the first semiconductor layer through the metal plug penetrating through the second semiconductor layer.

The semiconductor device according to one aspect of the present disclosure may be configured such that the drain region includes the first region and the second region disposed between the first region and the channel formation region, and the impurity concentration of the second region is lower than the impurity concentration of the first region.

In the semiconductor device according to one aspect of the present disclosure, the first semiconductor layer may be provided at the side wall of the second region.

What is claimed is:

1. A semiconductor device comprising
a plurality of column portions including a semiconductor,
the plurality of column portions each including:
a source region;
a drain region; and
a channel formation region located between the source region and the drain region,
the semiconductor device further comprising:
a gate electrode provided, via an insulating layer, at a side wall of the channel formation region and configured to control a current between the source region and the drain region; and
a first semiconductor layer provided at a side wall of the drain region, wherein
a conductive type of the first semiconductor layer differs from a conductive type of the semiconductor included in the drain region.

2. The semiconductor device according to claim 1, wherein the gate electrode includes polycrystalline silicon.

3. The semiconductor device according to claim 2, wherein the gate electrode is doped with boron.

4. The semiconductor device according to claim 1, wherein the semiconductor is gallium nitride.

5. The semiconductor device according to claim 1, wherein the first semiconductor layer is electrically coupled to the source region.

6. The semiconductor device according to claim 1, wherein a second semiconductor layer is coupled to the source region of each of the plurality of column portions.

7. The semiconductor device according to claim 6, wherein
the conductive type of the semiconductor and a conductive type of the second semiconductor layer are each an n-type, and
the conductive type of the first semiconductor layer is a p-type.

8. The semiconductor device according to claim 6, wherein a metal layer is coupled to the second semiconductor layer.

9. The semiconductor device according to claim 8, wherein
the source region is coupled to the metal layer and the first semiconductor layer through a metal conductive layer penetrating the second semiconductor layer.

10. The semiconductor device according to claim 1, wherein the drain region includes:
a first region; and
a second region located between the first region and the channel formation region, and
an impurity concentration of the second region is lower than an impurity concentration of the first region.

11. The semiconductor device according to claim 10, wherein
the first semiconductor layer is provided at a side wall of the second region.
